(19) United States
(12) Patent Application Publication
(10) Pub. No.: US 2022/0034828 A1
(43) Pub. Date: Feb. 3, 2022

(54) Method for Measuring Acid Anhydride Content

(71) Applicant: Nippon Telegraph and Telephone Corporation, Tokyo (JP)

(72) Inventors: Azusa Ishii, Tokyo (JP); Takashi Miwa, Tokyo (JP); Masamitsu Watanabe, Tokyo (JP); Soichi Oka, Tokyo (JP)

(21) Appl. No.: 17/417,672

(22) PCT Filed: Dec. 13, 2019
(86) PCT No.: PCT/JP2019/048939

§ 371 Date: Jun. 23, 2021

(30) Foreign Application Priority Data
Dec. 28, 2018 (JP) 2018-246654

(51) Int. Cl. G01N 24/08

(52) U.S. Cl. CPC G01N 24/088

(57) ABSTRACT

In a first step, a sample formed of a polyester or decomposition products of a polyester is dissolved in a pretreatment liquid containing a secondary amine to obtain a reaction product (amide) of the sample. In a second step, the obtained reaction product, amide, is mixed into a solvent containing deuterated chloroform and deuterated 1,1,1,3,3,3-hexafluoro-2-propanol to fabricate a sample liquid. In a third step, the amount of the amide in the sample liquid is measured through a nuclear magnetic resonance spectroscopy aiming at hydrogen atoms to determine the amount of acid anhydride in the sample.

### CROSS-REFERENCE TO RELATED APPLICATIONS

This patent application is a national phase filing under section 371 of PCT/JP2019/048939, filed Dec. 13, 2019, which claims the priority of Japanese patent application no. 2018-246654, filed Dec. 28, 2018, each of which is incorporated herein by reference in its entirety.

### TECHNICAL FIELD

The present invention relates to a method for measuring an acid anhydride content, and more particularly, to a method for measuring the content of acid anhydride in a degraded polyester.

### BACKGROUND

Polyesters having thermoplasticity (thermoplastic polyesters) have both strength and flexibility, and are utilized in a variety of applications as engineering plastics. For example, polyethylene terephthalate (PET), which is a thermoplastic polyester, is utilized in films, fibers, and bottles for beverages, some of which are also recycled.

Degradation of thermoplastic polyesters progresses due to heat or light, and it is industrially important to grasp the state of this degradation. Thermoplastic polyesters that have been degraded by light or heat are in a state of containing an acid anhydride structure (Non-Patent Literature 1). When this acid anhydride structure is hydrolyzed, the strength of the material is reduced due to breakage of the molecular chain, and therefore, it can be said that the content of the acid anhydride structure is an important indicator for evaluating the degradation of thermoplastic polyesters.

However, even when using either an infrared spectroscopy (IR measurement), which is effective in quantitative measurement of the molecular structure of polymers, or a nuclear magnetic resonance spectroscopy aiming at hydrogen atoms (¹H NMR measurement), it is difficult to measure the content of the acid anhydride structure in thermoplastic polyesters through existing methods.

The IR measurement can detect the acid anhydride structure contained in degraded thermoplastic polyesters (Non-Patent Literature 1). However, in order to convert the peak intensity of the infrared absorption spectrum obtained by the IR measurement into the concentration, it is necessary to obtain a calibration curve by measuring a standard sample in which the concentration of the molecular structure to be measured has been known (Non-Patent Literature 2, pp. 68 and 69). It is difficult to acquire standard samples of thermoplastic polyesters that contain the acid anhydride structure, which is a product due to the degradation of thermoplastic polyesters, at an arbitrary concentration; therefore, it is hard to quantify the content of the acid anhydride structure by the IR measurement.

In contrast, the ¹H NMR measurement allows the concentration to be calculated from the ratio of integrated values of the proton spectrum and does not require a standard sample for quantitative measurement. However, there has been no reported case where the acid anhydride structure contained in degraded thermoplastic polyesters is measured by ¹H NMR. As a general measurement condition for thermoplastic polyesters, a mixed solvent of deuterated chloroform (CDCl₃) and 1,1,1,3,3,3-hexafluoro-2-propanol-2d (HFIP-2d), or a mixed solvent of deuterated chloroform (CDC13) and trifluoroacetic acid-d (TFA-d) has been used as a solvent in which the sample thermoplastic polyester is dissolved (Non-Patent Literature 2, pp. 86 and 87). 1,1,1,3,3,3-hexafluoro-2-propanol-2d (HFIP-2d) is deuterated 1,1,1,3,3,3-hexafluoro-2-propanol.

However, in the measurement using these solvents, the peak derived from the acid anhydride structure cannot be detected because the peak derived from the acid anhydride structure overlaps with another peak derived from a component of the solvent.

Alternatively, as a method for quantitatively measuring the aromatic carboxylic acid terminal of thermoplastic polyesters, a method is also known in which the sample thermoplastic polyester is dissolved in a mixed solvent of deuterated chloroform (CDCl₃) and 1,1,1,3,3,3-hexafluoro-2-propanol-2d (HFIP-2d), an amine is added to this mixed solution, the mixed solution to which the amine has been added is heated, and the aromatic carboxylic acid terminal of the thermoplastic polyester is subjected to quantitative measurement. In this measurement, the acid anhydride structure is decomposed and it is difficult to detect and quantify peaks derived from the decomposition products separately from peaks of other components.

### CITATION LIST

### Non-Patent Literature

Non-Patent Literature 1: T. Grossetete et al., “Photochemical degradation of poly(ethylene terephthalate)-modified copolymer”, Polymer, vol. 41, pp. 3541-3554, 2000.

Non-Patent Literature 2: Hajime Ohtani, Nobuyuki Sato, Shigeru Takayama, Hironori Matsuda, and Yukitaka Goto, “The Japan Society for Analytical Chemistry, Applied Analysis 4”, edited by The Japan Society for Analytical Chemistry, supervised by Hiroki Haraguchi, Hideyuki Ishida, Hajime Ohtani, Koji Suzuki, Hiroko Seki, and Hitoshi Watarai, published in 2013.

### SUMMARY

### Technical Problem

As described above, the conventional measurement methods have the problem of not being able to measure the content of acid anhydride in the degraded polyester.

Embodiments of the present invention have been made in order to solve the problem as described above, and an object of embodiments of the present invention is to enable measurement of the content of acid anhydride in the degraded polyester.

### Means for Solving the Problem

A method for measuring the acid anhydride content according to embodiments of the present invention comprises: a first step of dissolving a sample formed of a polyester or decomposition products of a polyester in a pretreatment liquid containing a secondary amine to obtain a reaction product of the sample; a second step of mixing the reaction product into a solvent containing deuterated chloroform and deuterated 1,1,1,3,3,3-hexafluoro-2-propanol to fabricate a sample liquid; and a third step of measuring the amount of an amide in the sample liquid through a nuclear magnetic resonance spectroscopy aiming at hydrogen atoms to determine the amount of acid anhydride in the sample.

In one configuration example of the above method for measuring the acid anhydride content, two substituents of the secondary amine comprise aliphatic hydrocarbons.

In one configuration example of the above method for measuring the acid anhydride content, the two substituents of the secondary amine comprise the same aliphatic hydrocarbon.

In one configuration example of the above method for measuring the acid anhydride content, the pretreatment liquid contains chloroform in addition to the secondary amine.

In one configuration example of the above method for measuring the acid anhydride content, the mixing ratio of chloroform to the secondary amine in the pretreatment liquid is set to 3 or less in the volume ratio.

In one configuration example of the above method for measuring the acid anhydride content, in the first step, the sample is dissolved in the pretreatment liquid to obtain the reaction product by setting the temperature of the pretreatment liquid at 30° C. or higher and at or below the boiling point of a component with the lowest boiling point contained in the pretreatment liquid.

### Effects of Embodiments of the Invention

As described above, according to embodiments of the present invention, a sample formed of a polyester or decomposition products of a polyester is dissolved in a pretreatment liquid containing a secondary amine to obtain a reaction product of the sample, which enables the content of acid anhydride in the degraded polyester to be measured.

### BRIEF DESCRIPTION OF THE DRAWING

FIG. 1 is a flowchart for describing a method for measuring the acid anhydride content according to an embodiment of the present invention.

### DETAILED DESCRIPTION OF ILLUSTRATIVE EMBODIMENTS

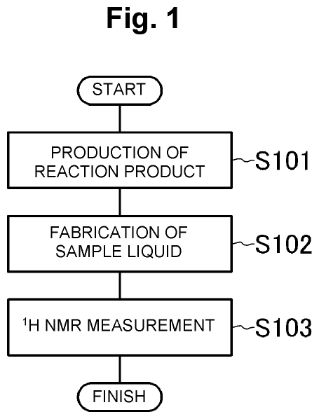

Hereinafter, a method for measuring the acid anhydride content according to an embodiment of the present invention will be described with reference to FIG. 1.

At first, in a first step S101, a sample formed of a polyester or decomposition products of a polyester is dissolved in a pretreatment liquid containing a secondary amine to obtain a reaction product (amide) of the sample. As the secondary amine, amines in which two substituents comprise aliphatic hydrocarbons (aliphatic substituents), such as diethylamine, can be used. In diethylamine, the two substituents comprise the same aliphatic hydrocarbon [(CH₂CH₃)]. Also, the pretreatment liquid may also have a configuration of containing chloroform in addition to the secondary amine. Note that the treatment of the first step will be referred to as a “pretreatment” in the following sections.

By dissolving a sample of thermoplastic polyester containing an acid anhydride structure in a pretreatment liquid containing diethylamine, the acid anhydride structure (1) is chemically converted in a selective manner by the following reaction (A) or reaction (B), and amides (2), (3), (4), and (5), which are the reaction products of the acid anhydride structure, can be obtained. Note that R1 is an aromatic ring and R2 is an aliphatic hydrocarbon. In addition, R3 and R4 are each an aliphatic substituent in the secondary amine.

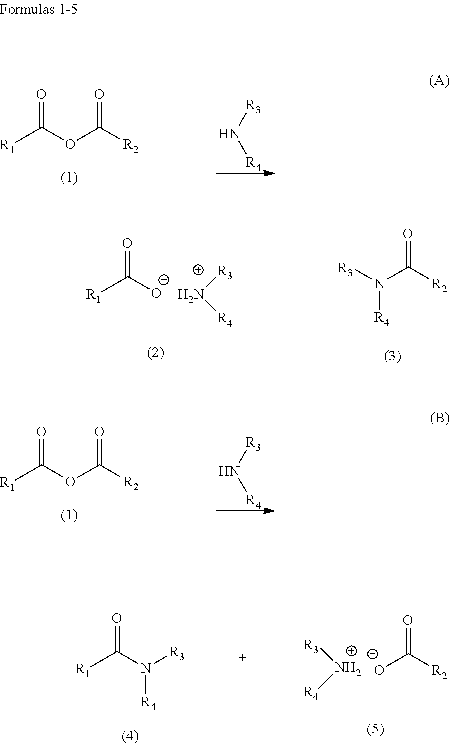

Subsequently, in a second step S102, the obtained reaction product, amide, is mixed into a solvent containing deuterated chloroform and deuterated 1,1,1,3,3,3-hexafluoro-2-propanol to fabricate a sample liquid. For example, the pretreatment solution in which the produced reaction product is dissolved is removed by volatilizing, and the resultant solid is dissolved in the deuterated solvent.

Next, in a third step S103, the amount of the amide (reaction product) in the sample liquid is measured through a nuclear magnetic resonance spectroscopy aiming at hydrogen atoms to determine the amount of the acid anhydride in the sample. In the third step S103, the amount of the amide, which is the reaction product of the acid anhydride structure mentioned above, is measured through a nuclear magnetic resonance spectroscopy aiming at hydrogen atoms to determine the amount of the acid anhydride structure in the sample liquid. Based on the obtained amount (total amount) of the acid anhydride structure, the degradation of the measured sample (polyester) is determined. For example, if the measurement results of the acid anhydride structure of the sample to be determined for degradation are increased to or above the reference value, the sample under consideration can be determined to be degraded.

### EXAMPLES

Hereinafter, more detailed description will be given using Examples.

Sample

Sample 1: Polyethylene terephthalate, about 3 mg.

Sample 2: A low molecular compound with an acid anhydride structure represented by the following chemical formula (6), about 3 mg.

Sample 3: A polyethylene terephthalate containing an acid anhydride structure (decomposition products of a polyester), about 3 mg.

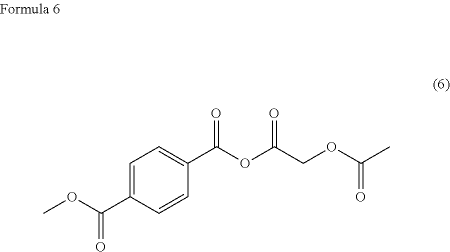 [SMILES: COC(=O)c1ccc(C(=O)OC(=O)COC(C)=O)cc1]

Pretreatment Liquid

The pretreatment liquid had a configuration where diethylamine (secondary amine) was mixed into chloroform. Note that, for comparison, pretreatment liquids using n-butylamine (primary amine) and isopropylamine (primary amine) instead of diethylamine were also prepared.

Measurement Solvent for Fabricating Sample Liquid

Measurement solvent 1: A solution obtained by mixing deuterated chloroform (CDCl₃) containing Me₄Si at 0.03% (v/v) and deuterated 1,1,1,3,3,3-hexafluoro-2-propanol-2d (HFIP-2d) in a volume ratio of 1:1.

Measurement solvent 2: A solution obtained by mixing CDCl₃ containing Me₄Si at 0.03% (v/v) and deuterated trifluoroacetic acid-d (TFA-d) in a volume ratio of 10:1.

Measurement solvent 3: A solution obtained by mixing CDCl₃ containing Me₄Si at 0.03% (v/v) and HFIP-2d in a volume ratio of 1:1 to obtain a solution and then adding about 3 mg of isopropylamine to 1.0 mL of the resultant solution.

Measurement solvent 4: A solution obtained by mixing CDCl₃ containing Me₄Si at 0.03% (v/v) and HFIP-2d in a volume ratio of 1:1 to obtain a solution and then adding about 3 mg of n-butylamine to 1.0 mL of the resultant solution.

Measurement solvent 5: A solution obtained by mixing CDCl₃ containing Me₄Si at 0.03% (v/v) and HFIP-2d in a volume ratio of 1:1 to obtain a solution and then adding about 3 mg of diethylamine to 1.0 mL of the resultant solution.

NMR Measurement

For each of the fabricated samples, ¹H NMR (300 MHz) was measured with a nuclear magnetic resonance device, Oxford, from Varian, Inc. Each sample was dissolved in each measurement solvent (about 0.9 mL) and the measurement was conducted at T° C. The chemical shift δ was expressed in ppm, with the peak of Me₄Si being 0 ppm.

Peak to be Measured

Protons (a) of the aromatic ring in the repeated structure of a polyester represented by the following chemical formula (a).

Protons (b) of the methylene group at the a position of the ester bond in the repeated structure of the polyester represented by the chemical formula (a).

Protons (c) and (c′) of the amin derivative of the carboxylic acid terminal of a polyester represented by the following chemical formula (7).

Protons (d) and (d′) of the aromatic ring in a compound represented by the following chemical formula (6). Note that, as mentioned above, the compound represented by the chemical formula (6) is a low molecular compound with an acid anhydride structure of the sample 2.

Protons (e) at the a position of the acid anhydride structure represented by the following chemical formula (6).

Protons (f) at the a position of the carbonyl carbon of the amide bond represented by the following chemical formula (8). Note that the amide bond represented by the chemical formula (8) is an amide converted product of the compound represented by the chemical formula (6).

Protons (g) of the aromatic ring represented by the following chemical formula (9). Note that the aromatic ring represented by the chemical formula (9) is an amide converted product of the compound represented by the chemical formula (6).

Protons (h) and (h′) of the aromatic ring in a decomposition product of an acid anhydride structure in a polyester represented by a chemical formula (10).

Protons (i) of the substituent R3 in a decomposition product of an acid anhydride structure in a polyester represented by the following chemical formula (11).

Protons (j) and (j′) at the β position of N in a decomposition product by diethylamine of an acid anhydride structure in a polyester represented by the following chemical formula (12).

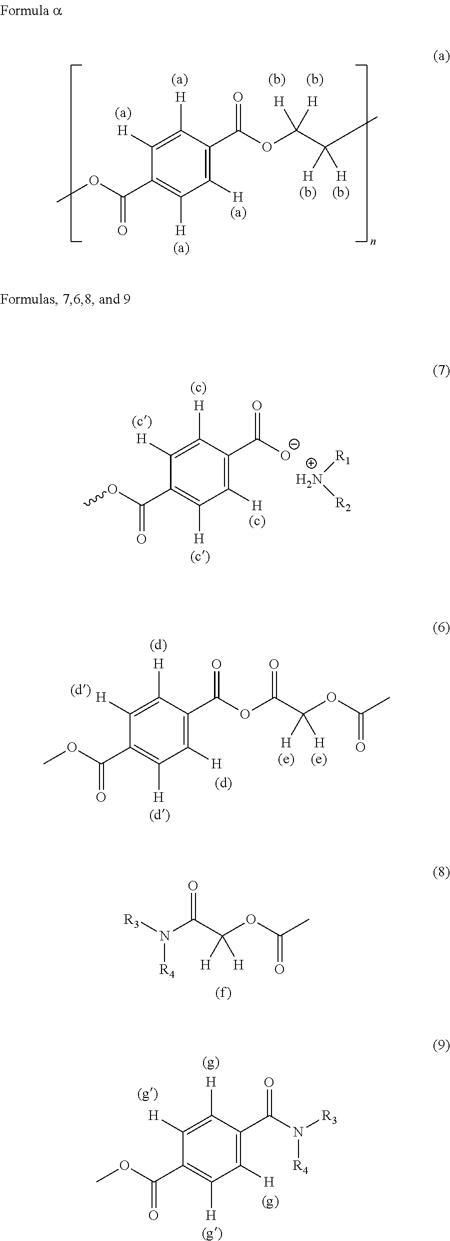

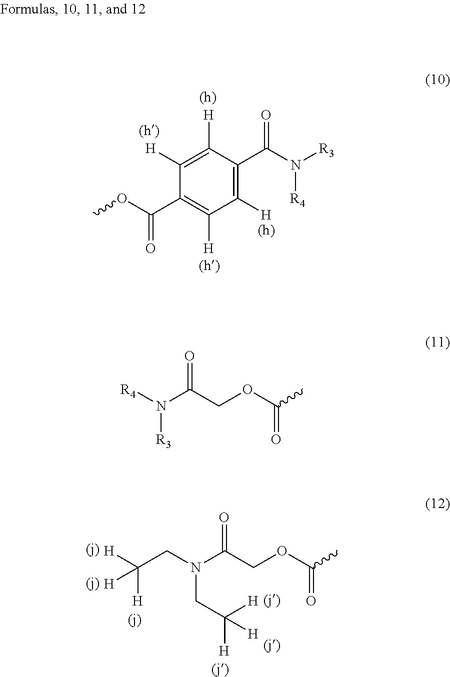

Note that, hereinafter, each of the compounds represented by the chemical formula (6), the chemical formula (7), the chemical formula (8), the chemical formula (9), the chemical formula (10), the chemical formula (11), and the chemical formula (12) will be referred to as a compound (6), a compound (7), a compound (8), a compound (9), a compound (10), a compound (ii), and a compound (12), respectively.

Study 1

Next, the peak detection position for measuring the decomposition product by diethylamine of the acid anhydride structure is studied. In this study, the peak detection position of protons derived from the acid anhydride structure in the existing NMR measurement method and the peak detection position of protons derived from a thermoplastic polyester are compared.

The sample 1 and the sample 2 were each dissolved in the measurement solvent 1, the measurement solvent 2, and the measurement solvent 3. For the samples dissolved in the measurement solvent 1 and the measurement solvent 3, the ¹H NMR measurement was carried out at T=50° C., and for the samples dissolved in the measurement solvent 2, the measurement was carried out at T=25° C. The results obtained by the above measurement, comparing the peak detection position of protons derived from the acid anhydride structure and the peak detection position of protons derived from the thermoplastic polyester, are shown in Table 1.

In the case of using the measurement solvent 1 and the measurement solvent 2, the peaks of the protons in the acid anhydride structure were all detected at the same positions as the peaks of the protons in the thermoplastic polyester. In addition, when the sample 2 was measured using the measurement solvent 3, several peaks of the protons in the aromatic ring were confirmed, indicating that the acid anhydride structure was decomposed, and most of the peaks of the decomposition products were detected at the same positions as the peaks of the thermoplastic polyester. From the above results, it was found that it is difficult to detect the acid anhydride structure contained in the thermoplastic polyester under the existing NMR measurement conditions.

TABLE 1
Comparison of the peak detection positions of protons derived from the low
molecular model compound with the acid anhydride structure and protons derived
from the thermoplastic polyester in the existing NMR measurement approach

| Measurement | | |
|---|---|---|
| conditions | (d) and (d′) of (sample 2) | (e) of (sample 2) |
| (Measurement solvent 1) | δ8.10: the same position as (a) | δ4.71: the same position as (b) |
| T₁ = 50° C. | of (sample 1) | of (sample 1) |
| (Measurement solvent 2) | δ8.09: the same position as (a) | δ4.70: the same position as (b) |
| T₁ = 25° C. | of (sample 1) | of (sample 1) |
| (Measurement solvent 3) | δ8.15: the same position as (a) | δ4.70: the same position as (e) |
| T₁ = 50° C. | of (sample 1) | of (sample 1) |
| | δ7.93: the same position as (c) | |
| | of (sample 1) | |
| | δ7.74: not overlapping with | |
| | peaks of (sample-1) | |

Method for Quantifying Acid Anhydride Structure

As a result of the study and discussion of the study 1 mentioned above, the molar concentration C [mol %] of the acid anhydride structure relative to the entire terephthalic acid structure in each sample was calculated using the integrated values of the peaks of any of the aforementioned protons obtained by NMR measurements for the decomposition product as “C={(h)×2+((j) +(j′))×k}/{(a)+(c)+(c′)+(h)+(h′)}×100 . . . (concentration calculation equation)”. Note that k is the value obtained by dividing 2 by the number of protons at the peak of (j).

Study 2 (Study on Pretreatment Method for Low Molecular Model Compound with Acid Anhydride Structure)

Next, the results of the study on the sample liquid fabricated in the second step will be described. The present inventors studied the conversion of the acid anhydride structure to a compound that can be detected by the ¹H NMR measurement through pretreatment. In order to make the acid anhydride structure detectable by the ¹H NMR measurement, it must be converted to a compound having a peak that is clearly distinguishable from the peaks of the thermoplastic polyester and the measuring solvent. In addition, in the process of the conversion mentioned above, the ester groups contained in the repeating units of the thermoplastic polyester and the carboxyl group and the hydroxyl group, which are the terminal functional groups of the thermoplastic polyester, must not be converted into the same compound as the compound after the conversion of the acid anhydride structure.

The present inventors have made diligent studies on the chemical conversion that satisfies the requirements mentioned above, and have come to study and verify by experiments a method in which the acid anhydride structure is converted into the compound (3) and the compound (4) by the reaction (A) and the reaction (B) and the protons of the compound (3) and the compound (4) are detected.

First of all, it was confirmed whether the reactions (A′) and (B′) shown below proceed quantitatively using representative amines (butylamine, isopropylamine, and diethylamine). To a solution obtained by adding an amine (conducted for each of butylamine, isopropylamine, and diethylamine) to chloroform, 3 mg of the sample 2 was added and dissolved by stirring for 5 minutes, and the solution (solvent) was volatilized and removed to obtain about 3 mg of a solid. When the obtained solid was dissolved in deuterated chloroform and subjected to the ¹H NMR measurement at T=25° C., it was confirmed that the reaction (A′) and the reaction (B′) proceeded quantitatively in each case of using any of the amines.

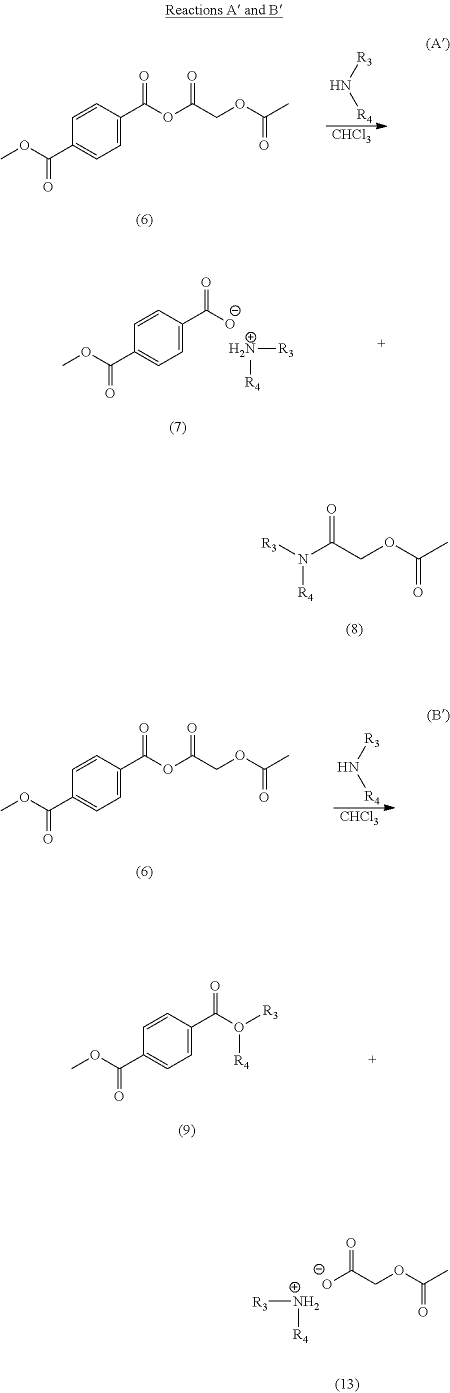

Next, the solvent of the sample liquid after conducting the measurement described above was volatilized to recover the sample, and an NMR measurement was conducted using a mixed solvent of HFIP and chloroform to which an amine that was the same as the amine used for the decomposition of the acid anhydride structure of the compound (6) was added. By this measurement, the peak detection positions of the compound (7), the compound (8), the compound (9), and the compound (13) by the reaction (B′) were compared with the peak detection position of the thermoplastic polyester (sample 1), and it was examined whether the compounds (7) to (9) and the compound (13) can be quantified in the case where the compounds (7) to (9), the compound (13), and the thermoplastic polyester coexist.

The compound (7) has the same molecular structure as the amine salt of the carboxylic acid terminal of the thermoplastic polyester, and therefore, the compound (7) cannot be quantified separately from the amine salt of the carboxylic acid terminal of the thermoplastic polyester.

The compound (8) will be mentioned later.

The compound (9) was found to be quantifiable under any of the measurement conditions, with the peak of the protons (g) of the aromatic ring being detected at a position that does not overlap with the peak of the thermoplastic polyester.

All peaks of the compound (13) overlapped with other peaks of the thermoplastic polyester, and the compound (13) was found to be unquantifiable.

From the above study results, it can be said that the acid anhydride structure can be quantified together with the quantification results of the compound (9) as long as the quantification is carried out under the conditions where the compound (8) can be quantified.

The peak of the protons (f) on the carbon at the α position of the carbonyl carbon of the amide bond in the compound (8) has the same peak position as that of the peak of (b) in the thermoplastic polyester under any of the measurement conditions, and it was found that the quantification using the peak of the protons (f) is not possible.

Table 2 shows the detectability of the peak of the protons of the substituent R₃ and the peak of the protons of the substituent R₄ of the compound (8) for each of the amines used. In the case of butylamine and isopropylamine, the peaks of the substituents overlap with the proton peak of the amine salt in the measurement system and are undetectable, whereas, in the case where diethylamine is used, the peaks of the substituents were found to be detectable separately from the amine salt in the measurement system.

TABLE 2
Detectability of the peaks of the protons of
R3 and the protons of R4 of the compound (8)

| | Measurement | |
|---|---|---|
| Amine | solvent | Detectability |
| Butylamine | (Measurement | Undetectable: the same |
| | solvent 4) | position as amin salt in |
| | | measurement system |
| Isopropylamine | (Measurement | Undetectable: the same |
| | solvent 3) | position as amin salt in |
| | | measurement system |
| Diethylamine | (Measurement | Detectable |
| | solvent 5) | |

This is thought to be because, unlike the primary amides produced when the primary amines butylamine and isopropylamine are used, the secondary amide produced when diethylamine is used has split peaks due to the rotational barrier of the amide bond. There has been no reported case of an approach utilizing peak splitting due to amide rotation in order to distinguish the peak of the amine salt from the peak of the amide, and this is not a method that can be easily conceived.

Experiment

Hereinafter, description will be given using the results of an experiment.

Into a mixed solution of diethylamine and chloroform at a volume ratio of 1:1, 3 mg of PET containing a sample 5 acid anhydride structure was placed, and dissolved by stirring at 40° C. for 4 hours. After this, the solvents in the solution were volatilized and removed. After dissolving the sample in the measurement solvent 1, a ¹H NMR measurement was carried out at 50° C., and the peaks of (h) and (j) and (j′) were detected.

(h): δ7.72

(j) and (j′): δ1.13 and 1.22

Substituting the integrated values of the detected peaks into the concentration calculation equation, “C={(h)×2+((j)+(j′))×2÷3}/{(a)+(c)+(c′)+(h)+(h′)}×100={0.15×2+(1.56+1.50)×2÷3}+/(42.73)×100=5.47” was obtained, and thus the molar concentration of the acid anhydride structure relative to the entire aromatic rings was calculated to be about 5.5 mol %.

Note that, although polyethylene terephthalate was used as the sample for the thermoplastic polyester in this experiment, it can be readily analogized that the measurement method mentioned above can also be applied to polybutylene terephthalate (PBT), polyneopentyl terephthalate (PNT), polyneopentyl isophthalate, and copolymers thereof.

Although diethylamine was used as the secondary amine in the above experiment, it can be readily analogized that dimethylamine, dipropylamine, diisopropylamine, dibutylamine, diisobutylamine, and the like can also be used. It is desirable that the types of the secondary amine used in the pretreatment and the amine added to the measurement solvent should be the same.

Note that, in order to easily distinguish the substituent R₃ and the substituent R₄ of N in the secondary amine from the aromatic ring peak of the thermoplastic polyester, aliphatic groups are suitably used therefor. Also, in order to reduce the number of peaks to be quantified, it is desirable that the substituent R₃ and the substituent R₄ should have the same molecular structure.

The temperature (reaction temperature) and the time in the pretreatment are appropriately set such that the chemical conversion of the acid anhydride structure is completed. Since the solubility of the thermoplastic polyester in amine and chloroform is low, it is desirable to dissolve the thermoplastic polyester by stirring it for several hours while heating it. In the pretreatment step (first step), the sample is dissolved in the pretreatment liquid by setting the temperature of the pretreatment liquid (reaction temperature) at 30° C. or higher and at or below the boiling point of a component with the lowest boiling point contained in the pretreatment liquid. Specifically, the sample is dissolved in the pretreatment liquid by setting the temperature of the pretreatment liquid at 30° C. or higher and at or below the lower boiling point among the boiling point of the secondary amine and the boiling point of the chloroform.

Next, the effect of the reaction temperature on the ¹H NMR measurement results will be described. The pretreatment was conducted under the same conditions as in the experiment mentioned above, using different pretreatment liquids and different reaction temperatures in the pretreatment step, and NMR measurements were carried out. The peaks of (h) and (j) and (j′) obtained as a result of the measurements were compared with those of the results of the experiment. The results of the comparison are shown in Table 3. Note that, in this comparison, the mixing ratio (volume ratio) of the secondary amines and chloroform in the pretreatment liquid was also changed, as shown in Table 3.

When the peaks of (h) and (j) and (j′) were detected at the same level as in the experiment, it was marked as good, and when the peak intensities of (h) and (j) and (j′) were smaller than those of the example, it was marked as poor. Note that, since the boiling point of diethylamine is 55° C., the cases where the reaction temperature was set to 20, 30, 40, and 50° C. were studied. In addition, as for the mixing ratio of the secondary amine and chloroform in the pretreatment liquid, the cases where it was set to 1:0.2, 1:1, 1:2, 1:3, and 1:4 were studied.

TABLE 3

| | Reaction | NMR measurement |
|---|---|---|
| | temperature in | results peak intensities |
| Pretreatment solution | pretreatment step | of (h) and (j) and (j′) |
| Diethylamine | 20 | Poor |
| Diethylamine | 30 | Good (t = 24) |
| Diethylamine | 40 | Good (t = 8) |
| Diethylamine | 50 | Good (t = 4) |
| Diethylamine/chloroform | 40 | Good (t = 4) |
| (1:0.2) | | |
| Diethylamine/chloroform | 40 | Good (t = 4) |
| (1:1) | | |
| Diethylamine/chloroform | 40 | Good (t = 8) |
| (1:2) | | |
| Diethylamine/chloroform | 40 | Good (t = 24) |
| (1:3) | | |
| Diethylamine/chloroform | 40 | Poor |
| (1:4) | | |

When the reaction temperature in the pretreatment step was set to 20° C., even though the reaction time was extended, the peak intensities of (h) and (j) and (j′) were smaller than those in the experiment, the amidation reaction did not progress sufficiently, and it was found to be too low for the pretreatment temperature. Moreover, when the reaction temperature was set to 50° C., the peak intensities of (h) and (j) and (j′) were almost at the same level as in the experiment. Even if the reaction temperature is raised to 55° C., which is the boiling point of diethylamine, as long as care is taken such that the amine is not completely evaporated, it is believed that the desired pretreatment can be conducted with no problem. Therefore, as for the reaction temperature in the pretreatment step, it can be said that a reaction temperature of 30 or higher, and at or below the boiling point of a component with the lowest boiling point contained in the pretreatment liquid, is suitably used.

Next, the mixing ratio of diethylamine and chloroform in the pretreatment liquid will be described. When the mixing ratio was set to 1:4, even though the reaction time was extended, the peak intensities of (h) and (j) and (j′) were smaller than those in the experiment, the amidation reaction did not progress sufficiently, and it was found that the concentration of the amine was too low. As such, since a low amine concentration in the pretreatment liquid requires a long reaction time, when chloroform is also added to the pretreatment liquid for use, the mixing ratio of chloroform to the secondary amine is set to 3 or less in the volume ratio.

As described above, according to embodiments of the present invention, a sample formed of a polyester or decomposition products of a polyester is dissolved in a pretreatment liquid containing a secondary amine to obtain a reaction product of the sample, which enables the content of acid anhydride in the degraded polyester to be measured.

It was difficult for the existing measurement method to measure the content of an acid anhydride structure contained in a thermoplastic polyester. In order to detect a molecular structure that is difficult to be measured directly, it is considered to convert the molecular structure to be detected into a detectable molecular structure, but the choice of this conversion reaction is important. This is because the thermoplastic polyester contains, in addition to the acid anhydride structure, carboxylic acid and hydroxy groups as functional groups that can be chemically converted.

The present inventors used representative amines to convert the acid anhydride structure into amides, and found that the peaks of the products, aliphatic amides, were likely to overlap with the peaks of the amine salts in the system and were not easy to be detected. From these results, the present inventors have made diligent studies and as a result, they have found that the aliphatic amide can be detected by utilizing a secondary amine. This can be understood as taking advantage of the fact that the proton peaks of the substituents on N of the secondary amide are separately detected by the rotational barrier of the amide bond. Embodiments of the present invention cannot be readily analogized because there has been no previous example of utilizing the splitting of the proton peaks of the substituents on N of the secondary amide for the detection of the acid anhydride structure using chemical conversion.

Note that the present invention is not limited to the embodiments described above, and it is obvious that those having ordinary skill in the art can make many modifications and combinations without departing from the technical idea of the invention.

1-6. (canceled)

7. A method for measuring an acid anhydride content, the method comprising:
a first step of dissolving a sample formed of a polyester or decomposition products of a polyester in a pretreatment liquid containing a secondary amine to obtain a reaction product of the sample;
a second step of mixing the reaction product into a solvent containing deuterated chloroform and deuterated 1,1,1,3,3,3-hexafluoro-2-propanol to fabricate a sample liquid; and
a third step of measuring an amount of an amide in the sample liquid through a nuclear magnetic resonance spectroscopy aiming at hydrogen atoms to determine an amount of acid anhydride in the sample.

8. The method according to claim 7, wherein two substituents of the secondary amine each comprise an aliphatic hydrocarbon.

9. The method according to claim 8, wherein the two substituents of the secondary amine each comprise the same aliphatic hydrocarbon.

10. The method according to claim 9, wherein the pretreatment liquid further contains chloroform in addition to the secondary amine.

11. The method according to claim 10, wherein a mixing ratio of the chloroform to the secondary amine in the pretreatment liquid is set to 3 or less in a volume ratio.

12. The method according to claim ii, wherein, in the first step, the sample is dissolved in the pretreatment liquid to obtain the reaction product by setting a temperature of the pretreatment liquid at 30° C. or higher and at or below a boiling point of a component with a lowest boiling point contained in the pretreatment liquid.

13. The method according to claim 7, wherein, in the first step, the sample is dissolved in the pretreatment liquid to obtain the reaction product by setting a temperature of the pretreatment liquid at 30° C. or higher and at or below a boiling point of a component with a lowest boiling point contained in the pretreatment liquid.

14. The method according to claim 7, wherein the pretreatment liquid further contains chloroform in addition to the secondary amine.

15. The method according to claim 14, wherein a mixing ratio of the chloroform to the secondary amine in the pretreatment liquid is set to 3 or less in a volume ratio.

16. The method according to claim 15, wherein, in the first step, the sample is dissolved in the pretreatment liquid to obtain the reaction product by setting a temperature of the pretreatment liquid at 30° C. or higher and at or below a boiling point of a component with a lowest boiling point contained in the pretreatment liquid.

17. A method for measuring an acid anhydride content, the method comprising:
dissolving a sample formed of a polyester in a pretreatment liquid containing a secondary amine to obtain a reaction product of the sample;
mixing the reaction product into a solvent containing deuterated chloroform and deuterated 1,1,1,3,3,3-hexafluoro-2-propanol to fabricate a sample liquid; and
measuring an amount of an amide in the sample liquid through a nuclear magnetic resonance spectroscopy aiming at hydrogen atoms to determine an amount of acid anhydride in the sample.

18. The method according to claim 17, wherein two substituents of the secondary amine each comprise an aliphatic hydrocarbon.

19. The method according to claim 18, wherein the two substituents of the secondary amine each comprise the same aliphatic hydrocarbon.

20. The method according to claim 17, wherein the pretreatment liquid further contains chloroform in addition to the secondary amine, and wherein a mixing ratio of the chloroform to the secondary amine in the pretreatment liquid is set to 3 or less in a volume ratio.

21. The method according to claim 17, wherein dissolving the sample comprises setting a temperature of the pretreatment liquid at 30° C. or higher and at or below a boiling point of a component with a lowest boiling point contained in the pretreatment liquid.

22. A method for measuring an acid anhydride content, the method comprising:
dissolving a sample formed of one or more decomposition products of a polyester in a pretreatment liquid containing a secondary amine to obtain a reaction product of the sample;
mixing the reaction product into a solvent containing deuterated chloroform and deuterated 1,1,1,3,3,3-hexafluoro-2-propanol to fabricate a sample liquid; and
measuring an amount of an amide in the sample liquid through a nuclear magnetic resonance spectroscopy aiming at hydrogen atoms to determine an amount of acid anhydride in the sample.

23. The method according to claim 22, wherein two substituents of the secondary amine each comprise an aliphatic hydrocarbon.

24. The method according to claim 23, wherein the two substituents of the secondary amine each comprise the same aliphatic hydrocarbon.

25. The method according to claim 22, wherein the pretreatment liquid further contains chloroform in addition to the secondary amine, and wherein a mixing ratio of the chloroform to the secondary amine in the pretreatment liquid is set to 3 or less in a volume ratio.

26. The method according to claim 22, wherein dissolving the sample comprises setting a temperature of the pretreatment liquid at 30° C. or higher and at or below a boiling point of a component with a lowest boiling point contained in the pretreatment liquid.
